(19) United States
(12) Patent Application Publication
(10) Pub. No.: US 2026/0002695 A1
(43) Pub. Date: Jan. 1, 2026

(54) DATA CENTER BUILDINGS AND ERECTION METHOD

(71) Applicant: PRIPCO LIMITED, Cheltenham (GB)

(72) Inventors: Aaron FAVILL, Leamington Spa (GB); Ashley RICHARDS, Tewkesbury Gloucestershire (GB)

(21) Appl. No.: 19/132,080

(22) PCT Filed: Nov. 24, 2023
(86) PCT No.: PCT/GB2023/053065

§ 371 Date: May 22, 2025

(30) Foreign Application Priority Data
Nov. 25, 2022 (GB) 2217689.5

(51) Int. Cl. F24F 13/02; E04H 5/00; H05K 7/20

(52) U.S. Cl. CPC F24F 13/0254; E04H 5/00; F24F 13/0245; E04H 2005/005; F24F 2221/36; H05K 7/20745

(57) ABSTRACT

A multi-level data center building, a kit of parts and a method for constructing such a building is disclosed. The data center building may have a plurality of data levels, each comprising a ceiling structure formed from a plurality of chassis units supported above the floor by a plurality of support posts. Optionally, there are a plurality of cold aisle chassis units interleaved with a plurality of hot aisle chassis units, joined together in an alternating side by side arrangement. Optionally, wherein the ceiling structure of a first data level forms the floor of a second data level, and side joins between cold aisle chassis units and hot aisle chassis units of the ceiling structure of the first data level are positioned under and extends along at least a portion of the length of rack storage areas of the second data level.

### PRIORITY CLAIM

The present application is a National Phase entry of PCT Application No. PCT/GB2023/053065, filed Nov. 24, 2023, which claims priority from Great Britain Patent Application Number 2217689.5, filed Nov. 25, 2022, the disclosures of which are hereby incorporated by reference herein in their entirety.

### FIELD OF THE INVENTION

The present invention concerns data centers and a method of constructing a data center. More particularly, but not exclusively, this invention concerns data center buildings, for example provided in sectional form. The invention also concerns a kit of parts for constructing a data center.

### BACKGROUND OF THE INVENTION

A data center is understood to be a large group of networked computer servers, typically provided in a dedicated space within a building. For example, a modern data center may include high density, high capacity IT systems in a specialist, dedicated space having a carefully controlled environment. A state of the art data center may include multiple data halls each containing hundreds or even thousands of computer servers, typically contained in racks arranged in rows. In general, each server is provided with electrical power and a network connection. During operation, components of servers typically generate heat, which should be dissipated to avoid overheating and damage to equipment. Organizations, and also individuals, treat data centers as mission-critical facilities, meaning that even short periods of down-time due to equipment malfunction is not tolerated. With the increase in demand for ‘cloud’ computing services, there is a need not only for additional data center facilities, but also higher capacity facilities. Alongside increases in computing power of individual servers, the number of servers in each rack, and the number of racks in each data hall increases with each new generation of data centers.

Various measures have been used to compare and contrast modern data centers, including the number of servers, building area, and power consumption. According to Data Centre Magazine, a hyperscale data center should exceed 5,000 servers and 10,000 square feet, and the three largest data center facilities in the world have total areas exceeding 7 million square feet. Hyperscale data centers often include multiple data halls, each being a single continuous space for accommodating servers. An individual data hall may include IT servers having a total power consumption of 3 MW or more. Racks, or cabinets, housing servers are typically arranged in rows separated by personnel aisles. In order to make efficient use of space, racks have become larger, and aisles longer. For example, a common modern rack design is capable of holding 42 servers stacked one on top the other (a ‘42U’ rack). The dimensions of server racks have become highly standardised, particularly in terms of width. Racks are typically 600 mm wide, and a 42U rack may have a height of about 2300 mm, a depth of 1050 mm, and once fully loaded with servers may weigh as much as 2.4 tonnes. A single row of racks in the data hall of a Hyperscale data center may be made up of 22 or more racks, with the data hall accommodating 14 or more rows. Such a high dead load weight concentrated in a relatively small area can present challenges in building design. For example, a single row of racks occupying a floor space of under 16 m² (i.e. a row of racks taking up 15 m by 1.05 m) may weigh as much as 62.5 tonnes.

Data centers are sophisticated installations usually requiring high levels of accuracy in construction. Such requirements can make deployment of new facilities costly and time consuming. Traditionally, data center facilities have been built using conventional construction methods, where a bespoke building shell is constructed first, and then fitted out with the necessary services and equipment on-site. In some instances, sophisticated ‘volumetric’ modular systems have been developed where modules of a data center are factory-finished off-site, then transported to site where all that is required is to connect modules together. An example of such a system is described in WO2010139921 (Bripco BVBA). WO2010139921 also describes an especially energy efficient data center layout, in which the data center is subdivided into segregated hot and cold zones, including alternating hot and cold aisles separated by rows of server cabinets. Each cold aisle is supplied with cooling air from a cold air corridor, that also functions as a personnel access corridor, that leads from an air handling unit. Another type of data center is disclosed in WO2013021182 (Bripco BVBA). A construction method is disclosed comprising the steps of: providing at least one ceiling portion, providing a plurality of supporting members, mounting services on the at least one ceiling portion, arranging the at least one ceiling portion and the plurality of supporting members into a first volume, transporting the ceiling portion and supporting members so arranged, and assembling the ceiling portion and supporting members to form a section of a data center, the section so formed having a second volume. The first volume is smaller than the second volume. A further type of system is the ‘plug and play’ kit of parts disclosed in WO2017129448 (Bripco BVBA). WO2017129448 discloses a kit of parts that can be used to rapidly and efficiently convert an existing building into a data center, by componentising the parts needed to equip a data hall.

There remains a need for a cost-effective, rapid and high precision system for construction of a data center. The present invention seeks to mitigate various problems of the prior art. Alternatively or additionally, the present invention seeks to provide an improved data center installation, and method of construction.

### SUMMARY OF THE INVENTION

The present invention provides, according to a first aspect, a multi-level data center building comprising a plurality of data levels. Optionally, each data level accommodates at least ten rack storage areas positioned on a floor, each rack storage area having a width and a length and being arranged to accommodate a row of at least ten server racks, the rack storage areas separating alternating hot aisles and cold aisles. Each cold aisle and each hot aisle has a width and a length. Preferably, each data level comprises a ceiling structure formed from a plurality of chassis units, each chassis unit having an elongate shape with a length and a width, opposed ends parallel to the width, opposed sides parallel to the length, and side beams extending along the opposed sides. Optionally, each chassis unit is supported above the floor by a plurality of support posts. Optionally, each plurality of chassis units includes a plurality of IT chassis units. It will be understood that an IT chassis unit forms a portion of the ceiling structure of a data level over at least part of an IT area. An IT area of a data center is an area in which IT equipment, particularly server racks, are accommodated. As used herein, an IT area comprises hot aisles, cold aisles and rack storage areas. It will be appreciated that an IT chassis unit may extend partially over further parts of a data level, for example extending across at least part of an ancillary area and/or a personnel access corridor (such as a cold corridor). Optionally, IT chassis units comprise cold aisle chassis units and hot aisle chassis units, for example arranged with cold aisle chassis units interleaved with a plurality of hot aisle chassis units. It will be understood that a cold aisle chassis unit typically aligns with an underlying cold aisle, thereby forming a portion of the ceiling structure that extends over and along at least part of the length of a cold aisle. Similarly, it will be understood that a hot aisle chassis unit typically aligns with an underlying hot aisle, thereby forming a portion of the ceiling structure that extends over and along at least part of the length of a hot aisle. Preferably, the side beams of neighboring chassis units abut (and are optionally joined together) at side joins. Optionally, there is an alternating side-by-side arrangement of cold chassis units and hot chassis units. The plurality of data levels includes a first data level, and a second data level positioned above the first data level. Optionally, the ceiling structure of the first data level forms the floor of the second data level. Preferably, each side join between chassis units (such as each side join between cold aisle chassis units and hot aisle chassis units) of the ceiling structure of the first data level is positioned under and extends along at least a portion of the length of a rack storage area of the second data level so that said rack storage area of the second data level spans a join between neighboring chassis units. Preferably, said side join runs along a line located in the middle third, for example approximately in the center, of the width of said rack storage area. Optionally, each side join is a continuous side join extending from one end of each chassis unit to the other end of each chassis unit. It has been found that such a data center building structure is especially effective and allows for particularly efficient manufacture and construction. In particular, forming the ceiling structure from chassis units allows the structure to be built up from a plurality of components that can be factory finished prior to arrival on site. Centralized factory manufacture provides a controlled environment and access to an experienced and highly skilled workforce, as well as allowing components to be constructed and tested while other works (such as ground preparation) take place on site. Dividing the ceiling structure into ‘cold aisle’ and ‘hot aisle’ chassis units allows the width of those units to be kept to a size that allows convenient transport, for example by road, and in particular allows the width to be kept within the limits of ‘regular’ load sizes, obviating the need for specialised equipment or additional safety precautions (such as road convoy escorts) during transport. A further advantage of dividing the ceiling structure into such chassis units, and arranging the units so that side joins underlie rack storage areas of the data level above is that the ceiling structure is strengthened at the points of highest load in a particularly efficient manner.

Optionally, each data level has a height of at least 4.5 m, such as at least 5.5 m. It will be understood that the height of a data level is the distance from the floor of one data level to the floor of the data level immediately above. The height thus includes the thickness of a chassis unit as well as the separation between chassis units of adjacent levels.

It will be understood that a rack storage area is a space sized and configured to accommodate the row of server racks, for example a row of at least 20 server racks. Optionally, the server racks that may be accommodated are 42U or larger server racks, meaning racking capable of holding 42 or more servers. In an air-cooled data center, IT equipment (which becomes hot during use) is cooled by contact with cooling air. Such cooling air may be supplied by one or more air handling units. As used herein: a ‘cold aisle’ of an operational data center is a space adjacent a row of racks (for example between opposed rows of racks) from which rack-mounted IT equipment is able to draw cooling air; a ‘hot aisle’ is a space adjacent a row of racks (for example between opposed rows of racks) into which rack-mounted IT equipment is able to expel warm air. Typically, operational efficiency is improved by segregating hot aisles and cold aisles, thereby avoiding cooling air in a cold aisle mixing with warm air from a hot aisle before being used to cool IT equipment. It will be appreciated that the ceiling structure is a structural component of the building, for example being a load-bearing structure of the building. Data center sections are also disclosed in WO2013021182 (Bripco BVBA), the contents of which are incorporated by reference. Optionally, side joins are formed by bolting or otherwise fastening adjacent chassis units together, for example via a bracket. For example, the abutting side beams of neighboring chassis may be bolted together, e.g., via a bracket. Optionally, when chassis are bolted together via brackets, said brackets may for example be bolted to each chassis unit (such as a side beam of each chassis unit), or each welded to a respective one chassis unit (such as a side beam of a chassis unit). Optionally, the brackets are multi-purpose brackets, such as multipurpose brackets for attaching neighboring chassis units together and for attachment of data center services suspended below each chassis unit. For example, each bracket is positioned and configured to fasten neighboring chassis units together and to provide an attachment point for a drop rod and/or a beam of a slot channel frame system. Such brackets are further described in the co-pending PCT application filed on the same day by the same applicant as the present application, with applicant's reference P036593WO and claiming priority from UK patent application no. 2217690.3 filed on 25 Nov. 2022 by the same applicant, the contents of which are fully incorporated herein by reference.

Optionally, the side beams are load-bearing structural beams that provide the main structural support for the chassis unit along its length. Optionally, the side beams are fabricated from metal, such as steel. For example, the beams are rolled steel joists. Optionally, the side beams are ‘I’ beams, so-called due to their cross-section having the shape of a capital letter i. Such beams are also known as universal beams, and/or ‘H’ beams. Optionally, each beam comprises top and bottom (e.g., planar) flanges joined by a (e.g., planar) web perpendicular to the flanges. It will be appreciated that such beams allow for neighboring beams to abut along straight edges, forming a tight join between neighboring chassis units.

Optionally, each chassis unit has end beams extending along the ends of the chassis unit. For example, each chassis unit may have a ‘ring beam’ structure, where beams extending along the sides and ends are joined together to form an outer framework. Optionally, each chassis unit has a planar shape, for example taking the form of a continuous solid panel. Optionally, each chassis unit comprises a plurality of cross-beams extending between opposed sides or ends (preferably sides), for example to support a covering that extends across the space between the side and/or end beams. It may be that such a ring beam structure provides a particularly rigid and strong construction. It will be appreciated that chassis unit beams may be formed from any suitable material, such as metal (e.g., steel).

Optionally, the plurality of data levels comprises a third data level positioned above the second data level. Optionally, the ceiling structure of the second data level forms the floor of the third data level, and each side join between chassis units (such as between cold aisle chassis units and hot aisle chassis units) of the ceiling structure of the second data level is positioned under and extends along at least a portion of the length of a rack storage area of the third data level so that said rack storage area of the third data level spans a join between neighboring chassis units. It will be appreciated that there may be further data levels, such as a fourth, fifth, sixth etc. data level, with corresponding arrangements of the ceiling structure.

It will be understood that each support post may be formed form a single piece of material, such as a metal (e.g., steel) beam, or multiple pieces secured together (such as multiple metal, e.g., steel, beams welded, bolted or otherwise fastened together. Optionally, each support post supports a portion of at least one chassis unit of the ceiling structure of the first data level and a portion of at least one chassis unit of the ceiling structure of the second data level. For example, each support post may support a portion of two or more chassis units of the ceiling structure of the first data level and two or more chassis units of the ceiling structure of the second data level. Optionally, each chassis unit of the ceiling structure of the first data level is supported by four or more support posts that also support a chassis unit of the ceiling structure of the second data level. It will be understood that each support post may support at least a portion of two or more, such as four, chassis units of each ceiling structure, for example wherein the support post is positioned at the intersecting corners of two or more, e.g., four, chassis units. Optionally, when the data center building comprises more than two data levels, the support posts each support at least a portion of at least one chassis unit of the ceiling structure of each data level. For example, the support posts may extend through two or more, such as all, data levels. Optionally, the chassis units are bolted or otherwise fastened to the support posts, optionally via one or more brackets. For example, the side and/or end beams of the chassis units are secured to the support posts. It will be appreciated that when brackets are used, such brackets may for example be bolted to the chassis and the post, or welded to one of the chassis or the post and bolted to the other (preferably welded to the post and bolted to the chassis, such as to a beam of the chassis).

Optionally, each IT chassis unit is arranged end to end with another IT chassis unit. Optionally, each cold aisle chassis unit is arranged end to end with an adjacent cold aisle chassis unit. Optionally, each hot aisle chassis unit is arranged end to end with an adjacent hot aisle chassis unit. In such an arrangement, it may be that chassis units are arranged in complementary pairs, for example so that the cold/hot aisles associated with each chassis unit together form a single continuous cold/hot aisle that extends along at least part of the length of each chassis unit. Optionally, such end to end arranged chassis units are spaced apart, for example having an insert bridging the gap between their ends. Optionally, the facing ends of such end to end arranged chassis units abut and are secured to a plurality of support posts (such as two support posts), for example so that said support posts support said ends of the chassis units. Optionally, such end to end adjacent chassis units are secured to and positioned on opposite sides of at least one, preferably two or more, support posts. For example, said support posts are sandwiched between the facing ends of the chassis units, e.g., positioned in a gap between said facing ends. It has been found that such positioning of the support posts allows neighboring side-by-side chassis units to have a continuous side join from one end of each chassis unit to the other.

It will be understood that each cold aisle chassis unit and each hot aisle chassis unit is associated with at least a portion of the length of an associated cold or hot aisle. For example, a cold or hot aisle chassis unit of the ceiling structure of a lower data level extends along and above a portion of a corresponding cold or hot aisle of that lower data level, and optionally extends along and below a portion of an aisle of a higher data level immediately above the lower data level. Optionally, the cold aisles of higher data levels overlie the cold aisles of lower data levels. Alternatively, it may be that the cold aisles of a higher data level overlie the hot aisles of a lower data level. Optionally, the width of a cold aisle chassis unit plus the width of a hot aisle chassis unit together correspond to: the width of a cold aisle, plus the width of a hot aisle, plus the width of two rack storage areas. For example, the width of a cold aisle chassis unit plus the width of a hot aisle chassis unit of the ceiling structure of the first data level correspond to the sum of the widths of the cold aisle, hot aisle and two rack storage areas of the first data level underlying the chassis units, and preferably also to the sum of the widths of the cold aisle, hot aisle and two rack storages areas of the second data level overlying the chassis units. It will be appreciated that since the side join between chassis units runs underneath a rack storage area, the width of ‘two rack storage areas’ referred to above is in practice made up of one complete rack storage area (spanning the join between the two chassis units), and portions of two separate rack storage areas that together add up to the width of a whole rack storage area (i.e. those that are on the outer sides of the two chassis units). Additionally or alternatively, the combined width of two neighboring chassis units of the plurality of chassis units (such as the combined width of any two neighboring IT chassis units) corresponds to: the width of a cold aisle, plus the width of a hot aisle, plus the width of two rack storage areas. Optionally, each cold aisle has a width of from 1 m to 2 m, such as 1.4 m to 1.6 m. Optionally, each hot aisle has a width of from 1 m to 2 m, such as 1 m to 1.4 m. Optionally, each rack storage area has a width of from 1 m to 1.5 m, such as about 1.2 m. Optionally, the width of a cold aisle chassis unit plus a hot aisle chassis unit is from about 5 m to about 7 m, preferably about 5 m to about 6 m. Optionally, each cold aisle chassis unit and each hot aisle chassis unit (such as all chassis units) has a width of from about 2 m to about 4 m, such as about 2.5 m to about 3.5 m. It may be that such a width allows for particularly convenient transport. Optionally, each chassis unit has a width equal to or less than the maximum permitted width for conventional road transport (e.g., in the UK, Europe, the US, Canada or Australia), for example without requiring special measures for ‘oversize’ loads. In the UK in 2022, a width of up to 2.9 m is permitted for normal loads. Optionally, the cold aisle chassis units and hot aisle chassis units have equal width. Optionally, all chassis units have an equal width. It may be that such an arrangement allows for particularly efficient manufacture and building layout flexibility. Optionally, chassis units have a length of from about 8 m to about 20 m, for example from about 10 m to about 16 m.

Optionally, each data level comprises a plurality of air handling units for providing cooling air to cold aisles. Optionally, the air handling units are direct air handling units. It will be understood that a direct air handling unit provides cooling air that comprises or consists of a portion of ambient air from outside the data center building, optionally where said ambient air is treated to adjust its temperature and/or humidity. Direct air handling units, and suitable control methodologies are disclosed in WO2011/148175A1 (Bripco BVBA), the contents of which are incorporated herein by reference. Alternatively, the air handling units are indirect air handling units. Suitable indirect air handling units are disclosed in WO2016/207323A1 (Bripco BVBA), the contents of which are incorporated herein by reference. It will be understood that an indirect air handling unit provides air that consists substantially of (for example consists entirely of) air from inside the data center building, optionally having been treated to adjust its temperature and/or humidity. Optionally, an indirect air handling unit comprises a heat exchanger for transferring heat from air inside the building to air from outside the building, for example wherein internal air travels through the air handling unit along an internal airflow path segregated from an external airflow path along which air from outside the building travels. Preferably, the air handling units comprise adiabatic cooling units, and optionally are free from mechanical cooling units (such as direct expansion cooling units). It will be understood that a direct expansion mechanical cooling unit provides cooling by contacting air with coils containing a refrigerant that had been compressed then allowed to expand. Optionally, the plurality of chassis units of the ceiling structure of the first data level comprises a plurality of air handler chassis units, each air handler chassis unit supporting a portion of an air handler of the second data level. Optionally, the plurality of chassis units of the ceiling structure of the second data level comprises a plurality of air handler chassis units, each air handler chassis unit supporting a portion of an air handler of the third data level, when the third data level is present. It will be appreciated that the data center building may optionally comprise additional data levels with corresponding arrangements of air handler chassis units. Optionally, each air handler chassis unit is joined to at least one other air handler chassis unit by a side join in a side-by-side arrangement. For example, the air handler chassis units are joined in a matter the same as or similar to the join between cold and hot aisle chassis units described herein above. Additionally or alternatively, the air handler chassis units are arranged end to end with an IT chassis unit (such as an adjacent cold aisle chassis unit or an adjacent hot aisle chassis unit). It will be understood that such an end to end arrangement may be the same as or similar to the end to end arrangement of chassis units described herein above. Additionally or alternatively, air handler chassis units may for example be supported by support posts in a manner the same as or similar to that described with reference to the chassis units above. Optionally, each air handler chassis unit has a width equal to the width of said adjacent IT chassis unit.

Optionally, the multi-level data center building comprises a service riser area, for example accommodating data center services extending between data levels. Optionally, the service riser area extends across multiple, e.g., all, data levels, for example providing a services route from lower to higher levels. Optionally, the plurality of chassis units of the ceiling structure of the first data level comprises a plurality of riser chassis units, each riser chassis unit comprising one or more (e.g., multiple) openings for accommodating passage of components of data center services though the chassis unit, for example from a level below the chassis unit to a level above the chassis unit. Optionally, each intermediate data level comprises one or more (e.g., multiple) such riser chassis units. Optionally, the one or more openings each have a cross-sectional area of at least 0.2 m², such as at least 5 m². Optionally, the one of more openings each have a minimum dimension across the opening of 0.3 m. Optionally, at least one of the one or more openings has a cross-sectional area of at least 1 m², such as 1 to 5 m². Optionally, at least one of the one or more openings has a minimum dimension across the opening of 1 m. It will be appreciated that the cross-sectional area of an opening is the size of the opening. Optionally, at least one of the openings is provided with a personnel safety rail around its perimeter. It will be understood that a safety rail may, for example, be in the form of a frame upstanding from the floor, sized and configured to present a person falling through the opening. Optionally, each riser chassis unit is joined to at least one other riser chassis unit by an end join in an end to end arrangement. For example, the riser chassis units are joined in a matter the same as or similar to the end to end arrangement of chassis units described herein above. Additionally or alternatively, the riser chassis units are arranged side-by-side with an adjacent cold aisle chassis unit or an adjacent hot aisle chassis unit. It will be understood that such a side-by-side arrangement may be the same as or similar to the join between chassis units described herein above. Additionally or alternatively, riser chassis units may for example be supported by support posts in a manner the same as or similar to that described with reference to the chassis units above. Optionally, each riser chassis unit has a length equal to the length of said adjacent IT chassis unit (e.g., cold aisle chassis unit or hot aisle chassis unit). Optionally, the plurality of riser chassis units comprises a plurality of intermediate riser chassis units and at least one roof riser chassis unit. It will be understood that an intermediate riser chassis unit is a chassis unit that forms a portion of an intermediate ceiling structure in the data center building, for example wherein the chassis unit forms a portion of the ceiling structure of a lower level and a portion of a floor of a higher level. It will be understood that a roof riser unit is a chassis unit that forms a portion of a ceiling structure of the top level of the data center building and a portion of the roof of the data center. Optionally, the data center comprises at least one riser head chassis unit, the riser head chassis unit comprising a riser head structure, e.g., projecting through and above the roof-level of the data center building. It will be understood that the roof-level of the building is the height of the roof formed by one or more chassis units adjacent the riser head chassis unit. Optionally, the riser head structure is in the form of a chamber having a height at least 1.5 m above the roof level, for example at least 2 m above the roof level. Optionally, the riser head chassis unit comprises a roof section, e.g., that forms a portion of the roof of the building level with the roof level of one or more neighboring chassis units in addition to the riser head structure. Optionally, the riser head structure is an integral part of the riser head chassis unit, for example wherein the riser head chassis unit is provided with a factory-finished weather-tight seal between the roof section and the riser head structure. Optionally, the riser head structure is accessible by personnel from the roof-top of the building, for example for maintenance or repair of service components in the riser, such as via a door provided in a side of the riser head structure. Optionally, the riser head structure comprises one or more service inlets for accommodating passage of service components between the interior of the riser head (and thus the interior of the building) and the exterior. For example, such an inlet may be configured to accommodate service components connected to roof-top equipment, such as heat exchange units.

Optionally, the or each data level comprises a cold air supply corridor having a length extending perpendicular to and being in fluid communication with the cold aisles of the data level to receive from the cold air supply corridor cooling air supplied to the cold air supply corridor by a plurality of air handling units. Optionally, the cold corridor transports cooling air to at least five cold aisles, such as at least seven cold aisles, and receives cooling air from at least three air handling units. A suitable cold corridor arrangement is described in WO2010139921 (Bripco BVBA), the contents of which are incorporated by reference. Specifically, that document describes a data center layout which utilizes personnel space for transport of large volumes of cooling air at low velocity, improving operating efficiency and making better use of space. Preferably, the air supply corridor is a personnel corridor, for example having a height of at least 3 m, such as at least 3.5 m, and a width of at least 2 m, such as at least 2.5 m, and optionally a length of at least 30 m, such as at least 40 m. Optionally, the air handling units are positioned alongside and distributed along the length of the cold air supply corridor. Optionally, during operation of the data center, cooling air from the air handing units enters the corridor through openings in the side of the corridor along its length. Optionally, the cold air supply corridor of the second data level, and the cold air supply corridor of the third data level if present (optionally also the cold air supply corridor of higher data levels, if present), extends across a plurality of side joins between adjacent chassis units, such as adjacent IT chassis units (e.g., cold aisle chassis units and hot aisle chassis units). It will be appreciated that in such an arrangement, at least a portion of the cold corridor occupies a space within an area bounded by IT chassis units (e.g., said cold aisle and hot aisle chassis units). Optionally, the cold air supply corridor of the second data level, and the cold air supply corridor of the third data level if present (optionally also the cold air supply corridor of higher data levels, if present), extends across a plurality of side joins between adjacent air handler chassis units. It will be appreciated that in such an arrangement, at least a portion of the cold corridor occupies a space within an area bounded by said air handler chassis units. Optionally, said cold corridor(s) span the ends of a plurality of IT chassis units (e.g., cold aisle chassis units and hot aisle chassis units) and air handler chassis units. It will be appreciated that in such an arrangement, at least a portion of the cold corridor occupies a space within an area bounded by IT chassis units (e.g., cold aisle chassis units and hot aisle chassis units) and air handler chassis units. For example, it may be that end to end joins between adjacent IT chassis units and air handler chassis units run in a line along the length of the cold corridor in the middle third, for example on or close to the center line, of the width of the cold corridor.

Optionally, each data level comprises a plurality of ancillary service space. Optionally, the plurality of chassis units of the ceiling structure of the first data level comprises a plurality of ancillary chassis units, each ancillary chassis unit supporting a portion of an ancillary space of the second data level. Examples of such ancillary service spaces include offices, maintenance rooms, control rooms, emergency power system rooms and staff facilities. Optionally, the plurality of chassis units of the ceiling structure of the second data level comprises a plurality of ancillary chassis units, each ancillary chassis unit supporting a portion of an ancillary space of the third data level, when the third data level is present. It will be appreciated that the data center building may optionally comprise additional data levels with corresponding arrangements of ancillary chassis units. Optionally, each ancillary chassis unit is joined to at least one other chassis unit by a side join in a side-by-side arrangement. For example, the ancillary chassis units are joined to other chassis units in a matter the same as or similar to the join between chassis units described herein above. Additionally or alternatively, the ancillary chassis units are arranged end to end with an adjacent chassis unit. It will be understood that such an end to end arrangement may be the same as or similar to the end to end arrangement of chassis units described herein above. Additionally or alternatively, ancillary chassis units may for example be supported by support posts in a manner the same as or similar to that described with reference to the chassis units above.

Optionally, the plurality of data levels comprises an uppermost data level, the ceiling structure of the uppermost data level forming at least a portion of a roof of the multi-level data center. Additionally or alternatively, the plurality of data levels comprises a lowermost data level, the floor of the lowermost data level being the ground floor of the multi-level data center.

Optionally, the ceiling structure comprises one or more service cassettes suspended from chassis units, such as IT chassis units. Service cassette systems are also disclosed in WO2017129448 (Bripco BVBA), the contents of which are incorporated by reference. Specifically, that document discloses cassettes suspendable from a building structure and equipped with air entrainment panels and data center services. Preferably, each service cassette comprises components of a plurality of data center services, such as at least three services. For example, components may include a conduit for fire suppressant fluid, a cable tray, electrical power components (such as cabling and/or a bus-bar), networking cabling, lighting equipment and/or sensor equipment (such as motion, temperature and/or humidity sensor equipment). Additionally or alternatively, one or more such services may for example be mounted directly on chassis units, independently of such service cassettes. Optionally, each service cassette comprises aisle air entrainment panels configured to cooperate with racks of IT equipment to segregate the hot and cold aisles. Optionally, at least a portion of such aisle entrainment panels comprise one or more service pass-through openings for accommodating service components extending between hot and cold aisles, optionally wherein said pass-through openings comprise one or more sealing openings for sealing around said service components to maintain air segregation between the hot and cold aisles. Optionally, each service cassette comprises ceiling air entrainment panels configured to segregate cold aisles from a hot air plenum disposed between the ceiling air entrainment panels and said chassis unit, said hot air plenum being in fluid communication with one or more hot aisles. Optionally, such service cassettes are suspended from hot aisle chassis units. It has been found that with such an arrangement, aisle entrainment panels on such a service cassette may conveniently define a warm air passageway providing fluid communication between a hot aisle and the hot air plenum. Additionally or alternatively, the ceiling structure comprises a plurality of ceiling air entrainment panels suspended from chassis units, for example by drop rods secured to chassis unit brackets and/or beams of a framework secured to chassis units. Optionally, such panels are suspended from cold aisle chassis units. Optionally, each data center comprises a hot air plenum for receiving hot air from hot aisles and transporting hot air to air handling units and/or exhaust vents (e.g., on the exterior of the building). Optionally, said hot air plenum extends above the cold aisles, for example being segregated from said cold aisles by ceiling air entrainment panels. Optionally, the plenum has an internal height of at least 0.5 m, such as at least 0.6 m, for example above each cold aisle. It will be understood that the internal height of the plenum is the distance across the gap between air entrainment panels segregating the plenum from a cold area, such as a cold aisle, and the ceiling structure.

Optionally, the data center building comprises a plurality of racks of IT equipment accommodated in the rack storage areas of each data level. Preferably, each rack is capable of holding at least 20, such as at least 30, optionally at least 40, items of rack-mountable IT equipment. Optionally, the racks together with air entrainment panels segregate the hot and cold aisles. Optionally, the data center building is a hyperscale data center building, for example accommodating at least 5,000 servers (rack-mountable items of IT equipment), and/or having an IT floor-space of at least 10,000 square feet. It will be understood that IT floor-space is the sum total of space occupied by rack storage areas, cold aisles and hot aisles, in the data center building. Optionally, each data level comprises at least 15 rack storage areas each able to accommodate at least 20 racks, for example wherein each data level is configured to accommodate at least 300 racks, for example 300 racks capable of housing at least 40 severs. In such an arrangement, each data level is optionally capable of accommodating at least 12,000 servers. Optionally, each data level has a single IT area comprising rack storage areas, cold aisles and hot aisles. It will be appreciated that each data level may for example accommodate two or more separate IT areas. Optionally, each IT area is configured to accommodate at least 12,000 servers. Optionally, each IT area occupies a floor space of at least 1,000 square meters. A hyperscale data center building may be one that is configured, when fully operational, to be capable of operating at total power levels of at least 40 MW.

While many benefits of the present invention may be particularly suited to embodiments in which the data center building is a hyperscale data center building, there may be comparable benefits to be had in large-scale, not necessarily, hyperscale data center facilities. A large scale facility may for example accommodate at least 2,000 servers (rack-mountable items of IT equipment), and/or have an IT floor-space of at least 500 square meters and/or be configured, when fully operational, to be capable of operating at total power levels of at least 10 MW.

According to a second aspect of the invention there is also provided a kit of parts for forming at least a section of a data center building, for example a data center building according to the first aspect of the invention. Optionally, the kit of parts comprises a plurality of IT chassis units (such as a plurality of cold aisle chassis units and a plurality of hot aisle chassis units), and optionally a plurality of support posts, as described in accordance with the first aspect of the invention. Optionally, the kit of parts comprises a plurality of support posts, optionally where each support post is configured for supporting at least a portion of each of two or more chassis units of a first data level and at least a portion of each of two or more chassis units of a second data level. It will be appreciated that the support posts may optionally be as described in relation to the first aspect of the invention herein above. Optionally, the kit of parts comprises a plurality of air handler chassis units, such as air handler chassis units as described with reference to the first aspect of the invention.

Optionally, the kit of parts comprises a plurality of riser chassis units, and/or one or more riser head chassis units, such as riser chassis units and/or one more riser head chassis units as described with reference to the first aspect of the invention.

Optionally, the kit of parts comprises a plurality of ancillary chassis units, such as ancillary chassis units as described with reference to the first aspect of the invention. Optionally, all chassis units of the kit of parts have equal width.

Optionally, the kit of parts comprises a plurality of service cassettes configured for suspension from a chassis unit (e.g., an IT chassis unit). Optionally, the kit of parts includes two or more service cassettes per hot aisle chassis unit. Optionally, each cold aisle service cassette comprises components of a plurality of data center services, for example components as described in relation to the cold aisle service cassettes of the first aspect of the invention. Additionally or alternatively, each cold aisle cassette comprises aisle air entrainment panels configured to cooperate with racks of IT equipment to segregate the hot and cold aisles. Additionally or alternatively, each cold aisle cassette comprises ceiling air entrainment panels configured to segregate cold aisles from a hot air plenum disposed between the ceiling air entrainment panels and said chassis unit. Additionally or alternatively, the kit or parts optionally comprises a plurality of ceiling air entrainment panels suspendable from chassis units, and optionally a plurality of drop rods securable to chassis units. Optionally, such panels are suspended from cold aisle chassis units. Optionally, the kit of parts includes multiple ceiling air entrainment panels per cold aisle chassis unit. Optionally, said hot air plenum is in fluid communication with one or more hot aisles. It will be appreciated that the service cassettes may include any feature as described in relation to the service cassettes of the first aspect of the invention. Optionally, the service cassettes are fastened to IT chassis units. For example the service cassettes are suspended from the IT chassis units by a plurality of supports (such as connecting rods, bars or wires). Preferably, the service cassettes are movable between (1) a first transport configuration in which the ceiling air entrainment panels are spaced apart from the IT chassis unit by a first distance, and (2) a second deployed position in which the ceiling air entrainment panels are spaced apart from the IT chassis unit by a second distance. Optionally, the first distance is less than the second distance. For example, the services cassettes each comprise a frame upon which service components and/or entrainment panels are mounted, the frame being movable along the supports (e.g. rods, bars or wires) by which they are attached to the chassis units. Optionally, the first distance is less than about 100 mm, for example less than about 50 mm. Optionally, the second distance is from about 200 mm to 2000 mm, for example from about 500 mm to about 1000 mm. It has been found that moving service cassettes between such transport and deployed configurations allows for more efficient use of space during transport, and also helps to reduce undue strain on service cassette supports during transport, especially if the chassis-cassette assembly is subjected to lateral movement.

Optionally, the kit of parts includes a plurality of air handling units, optionally wherein said units are transportable separately to the air handling chassis units.

According to a third aspect, there is provided a method of constructing a multi-level data center building. Optionally, the building is according to the first aspect of the invention. Optionally, the method comprises providing a kit of parts according to the second aspect of the invention. Optionally, the method comprises transporting the kit of parts in a first transport configuration, and subsequently assembling the kit of parts to form at least a section of the data center building. Preferably, the kit of parts occupies a first sum volume in the transport configuration, and a second sum volume once assembled. Preferably, the first sum volume is smaller than the second sum volume, for example wherein the first sum volume is less than half, for example less than a third, of the second sum volume.

Optionally, service cassettes are fastened to chassis units during the transporting step. Optionally, the service cassettes are arranged in a transport configuration during the transporting step. Optionally, the method comprises moving the service cassettes from the transport configuration to the deployed configuration during or after the assembling step.

According to a fourth aspect, there is provided a method of constructing a multi-level data center building, the method comprising bringing together at a construction site multiple prefabricated chassis units each having an elongate shape with a length and a width, opposed ends parallel to the width, opposed sides parallel to the length, and side beams extending along the opposed sides. The method further comprises, at the construction site, supporting the chassis units so that they form a ceiling structure of a first level of the building and so that the side beams of neighboring chassis units abut each other at side joins. The method further comprises forming, above the chassis units, a plurality of cold aisles in the data center interleaved with a plurality of hot aisles in the data center such that a rack storage area is defined between each pair of adjacent hot aisle and cold aisle, each such rack storage area spanning the side join between neighboring chassis units, wherein said ceiling structure forms a floor of a second level of the building above the first level. Optionally, the method comprises utilizing the kit of parts of the second aspect of the invention. Optionally, the method comprises arranging chassis units and/or support posts as described in relation to the first aspect of the invention. It will be appreciated that the method may for example be a method of constructing a data center building according to the first aspect of the invention.

According to a fifth aspect of the invention, there is provided a service cassette suspendable from a ceiling structure of a data center building (e.g., from a chassis unit forming a portion of such a ceiling structure). Preferably, the service cassette comprises components of a plurality of data center services, such as at least three services. For example, components may include a conduit for fire suppressant fluid, a cable tray, electrical power components (such as cabling and/or a bus-bar), networking cabling, lighting equipment and/or sensor equipment (such as motion, temperature and/or humidity sensor equipment). Optionally, the service cassette comprises aisle air entrainment panels configured to cooperate with racks of IT equipment to segregate hot and cold aisles in the data center building. Optionally, at least a portion of such aisle entrainment panels comprise one or more service pass-through openings for accommodating service components extending between hot and cold aisles, optionally wherein said pass-through openings comprise one or more sealing openings for sealing around said service components to maintain air segregation between the hot and cold aisles. Optionally, the service cassette comprises ceiling air entrainment panels configured to segregate cold aisles from a hot air plenum disposed between the ceiling air entrainment panels and a chassis unit forming a portion of a ceiling structure of a data center. Optionally, the service cassettes are configured for adjustable attachment to such chassis units, for example wherein the service cassettes comprise a plurality of supports (such as connecting rods, bars or wires) for suspending the service cassette from chassis units. Preferably, the service cassette is configured to be movable between (1) a first transport configuration in which the ceiling air entrainment panels are spaced apart from the chassis unit by a first distance, and (2) a second deployed position in which the ceiling air entrainment panels are spaced apart from the chassis unit by a second distance. Optionally, the first distance is less than the second distance. For example, the services cassette comprises a frame to which service components and air entrainment panels are attached, and a plurality of supports (e.g., rods, bars or wires) for suspending the service cassette from a ceiling structure (e.g., chassis units of the ceiling structure), optionally wherein the frame is movable along the supports, e.g., to vary the distance between the frame and said ceiling structure when the service cassette is suspended from the ceiling structure. Optionally, the supports comprise movable fastenings for controlling movement of the frame along the supports. For example, the supports comprise threaded sections on which a nut can be retained, for example wherein the frame rests upon or engages with the nut so that movement of the nut along the support allows or controls movement of the frame along the support. Optionally, the first distance is less than about 100 mm, for example less than about 50 mm. Optionally, the second distance is from about 200 mm to 2000 mm, for example from about 500 mm to about 1000 mm.

It will of course be appreciated that features described in relation to one aspect of the present invention may be incorporated into other aspects of the present invention. For example, the method of the invention may incorporate any of the features described with reference to the apparatus of the invention and vice versa.

### BRIEF DESCRIPTION OF THE DRAWINGS

Embodiments of the present invention will now be described by way of example only with reference to the accompanying schematic drawings of which:

FIG. 1 shows a side cross-sectional view of a multi-level data center building according to an embodiment of the invention;

FIG. 2 shows an enlarged portion of the drawing of FIG. 1;

FIG. 3 shows a further enlarged portion of the drawing of FIG. 1;

FIG. 4 shows an end cross-sectional view through a portion of the data center of FIG. 1;

FIG. 5 shows an enlarged view of a portion of FIG. 4;

FIG. 6 shows another side cross-sectional view through the data center of FIG. 1;

FIG. 7 shows an enlarged view of a portion of the drawing of FIG. 6;

FIG. 8a shows a plan view of a data level of the data center of FIG. 1;

FIG. 8b shows the plan view of FIG. 8a, overlaid with dashed lines showing the position of chassis units of the ceiling structure underlying the floor on which the data level is arranged;

FIG. 8c shows the plan view of FIG. 8a, annotated to show the positions of the views of FIGS. 1, 4 and 6 in the data center building;

FIG. 9 shows an end cross-sectional view of another data center according to an embodiment of the invention;

FIG. 10 shows an enlarged view of a portion of the drawing of FIG. 9; and,

FIG. 11 depicts steps of a method according to an embodiment of the invention.

### DETAILED DESCRIPTION

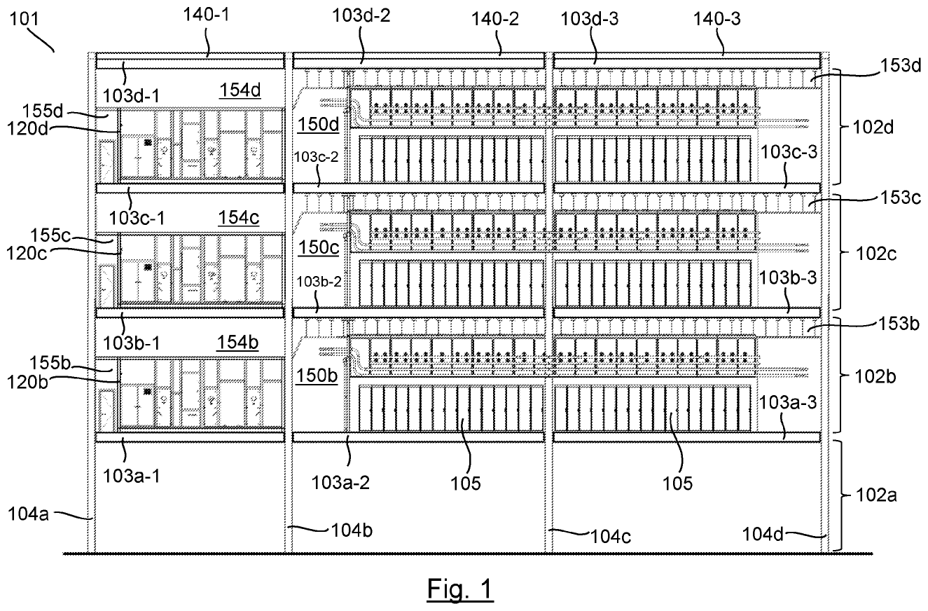

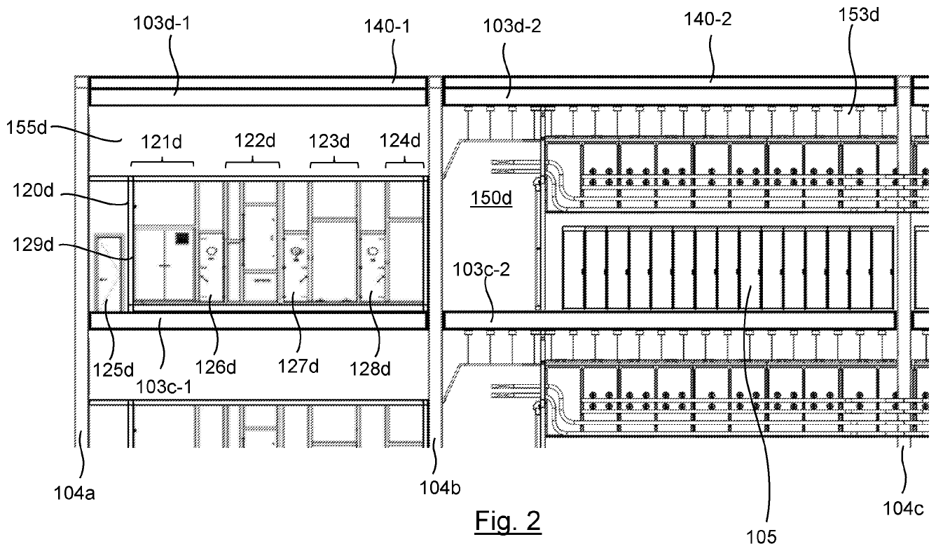

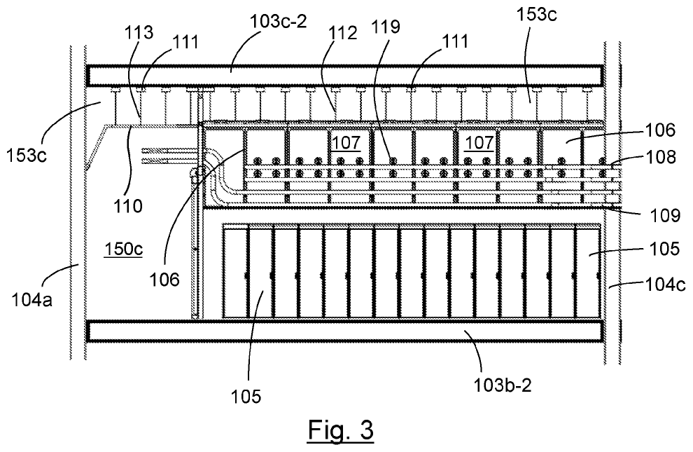

FIG. 1 shows a side cross-sectional view of a multi-level data center building 101 according to the invention. The building 101 comprises a mechanical and electrical services level 102a on the ground floor, and three data levels 102b, 102c, 102d on the floors above. Each level 102a-d of the building 101 comprises a ceiling structure formed from a plurality of chassis units 103, chassis units 103a-1 to 103a-3 forming the ceiling structure of level 102a, chassis units 103b-1 to 103b-3 for level 102b, chassis units 103c-1 to 103c-3 for level 102c, and chassis units 103d-1 to 103d-3 for level 102d. It will be understood that chassis units are in general referred to with the reference number 103, with specific chassis units and types of chassis units being given a suffix, and that a side-view of the chassis units 103 is shown in FIG. 1. The ends of the chassis units are supported by and fastened to support posts, with the chassis units shown in FIG. 1 being supported by eight support posts (only four support posts 104a-d are shown in FIG. 1). The support posts 104a-d are made up of multiple sections secured end to end. The mechanical and electrical services level 102a houses ancillary equipment, including ‘uninterrupted power supply’ (UPS) equipment, and power and data distribution equipment, not shown in FIG. 1. Each data level 102b-d comprises twenty rack storage areas arranged between alternating hot and cold aisles, with each rack storage area accommodating a row of 31 server racks 105. The server racks each hold up to 42 servers. The view shown in FIG. 1 cuts along a cold aisle, and thus illustrates the fronts of server racks 105. Further features of the data levels 102b-d are described below with reference to FIGS. 2 and 3. Chassis units 103a-2 and 103a-3 form part of the ceiling structure of the services level 102a, and part of the floor of the first data level 102b. Chassis units 103b-2 and 103b-3 form part of the ceiling structure of the first data level 102b, and part of the floor of the second data level 102c. Chassis units 103c-2 and 103c-3 form part of the ceiling structure of the second data level 102c, and part of the floor of the third data level 102d. Chassis units 103d-2 and 103d-3 form part of the ceiling structure of the third data level 102d, and part of the roof of the building 101.

Each data level 102b-d comprises a plurality of air handling units for providing cooling air to the cold aisles. FIG. 1 shows air handling units 120b-d of data levels 102b-d, respectively. Illustrated in FIG. 1 are the side covers and access doors of the air handler units 120b-d. Air handler chassis units 103b-1, 103c-1 and 103d-1 form part of the ceiling structure of data levels 102b-d, respectively, above air handler units 120b-d. Air handler chassis unit 103b-1 forms part of the floor of data level 102c, and supports a portion of air handler 120c. Air handler chassis unit 103c-1 forms part of the floor of data level 102d, and supports a portion of air handler 120d. Air handler chassis unit 103d-1 forms part of the roof of the building 101, comprising roof covering sections 140-1, 140-2 and 140-3, respectively. Chassis unit 103a-1 forms part of the ceiling structure of the services level 102a, and supports a portion of air handler 120b.

When the data center 101 is operational, cooling air is supplied by air handler units 120b/c/d into cold corridors 150b/c/d, respectively. The cold corridors 150b/c/d run perpendicular to cold aisles, receiving cooling air from the multiple air handlers on each data level and transporting said cooling air to the multiple cold aisles. From the cold aisles, cooling air passes into server racks 105, thereby cooling the servers and becoming warm air and exiting into the hot aisles. Warm air passes upwards from the hot aisles to overhead warm air return plenums 153b/c/d on each level, and then into a warm air return space 154b/c/d above the air handler units 120b/c/d. From that space, warm air may be ejected from the building through warm air exhaust vents (not shown in FIG. 1) and/or passed into mixing chambers 155b/c/d upstream of the air handler units 120b/c/d for mixing with ambient air from outside the building 101. Ambient air enters the mixing chambers 155b/c/d through air intake vents (not shown in FIG. 1).

FIG. 2 shows an enlarged portion of the drawing of FIG. 1, annotated with the same reference numerals as used in FIG. 1. As shown in FIG. 2 with reference to air handler unit 120d, the air handler unit 120d is made up of multiple sections. The sections include a filter bank 121d, a fan bank 122d, an adiabatic cooler (such as a wetted matrix cooling system) 123d, and an air blender 124d. An access door 125d provides access to the mixing chamber 155d, and further access doors 126d, 127d and 128d provide access to the section of the air handler 120d. The air handler sections are mounted in a support frame 129d.

FIG. 3 shows a further enlarged portion of the drawing of FIG. 1, annotated with the same reference numerals as used in FIG. 1. In FIG. 3, a portion of a row of IT racks 105 is shown supported on the floor formed by chassis unit 103b-2, and a corresponding row of service cassettes 106 is shown suspended from the ceiling structure formed by chassis unit 103c-2 above the IT racks 105. The service cassettes 106 are shown comprising air entrainment panels 107, electrical cable trays 108 and network cable trays 109 above the IT racks 105. Further air entrainment panels 110 are suspended from the chassis unit 103c-2 forming the ceiling separating the cold corridor 150c from the warm air plenum 153c. The air entrainment panels 107 of the service cassettes 106 segregate the hot and cold aisles. Openings 119 in panels 107 are provided to accommodate services passing between hot and cold aisles. The openings include adjustable covers to maintain air segregation between aisles. Brackets 111 depend from chassis unit 103c-2 forming part of the ceiling structure, and are arranged along the sides of the chassis unit 103c-2 so that they align back-to-back with corresponding brackets on adjacent chassis units (not shown in FIG. 3). Drop-rods 112 fastened to brackets 111 support the service cassettes 106. Further drop-rods 113 secured to slot channel beams (not shown in FIG. 3) fastened to brackets 111 support the air entrainment panels 110. The brackets 111 perform the dual function of securing adjacent chassis units 103 together (when corresponding brackets are bolted together) and providing suspension points for data center services. Further details are disclosed in a co-pending PCT application filed on the same day by the same applicant as the present application, with applicant's reference P036593WO and claiming priority from UK patent application no. 2217690.3 filed on 25 Nov. 2022 by the same applicant, the contents of which are fully incorporated herein by reference.

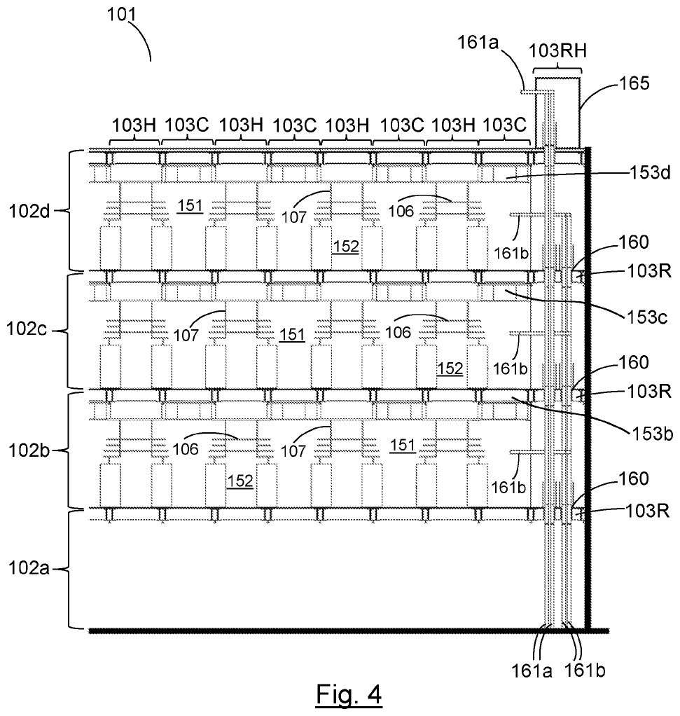

FIG. 4 shows an end cross-sectional view through a portion of the data center 101 of FIG. 1. As in FIG. 1, FIG. 4 shows services level 102a and data levels 102b-d. A view cutting across the widths of chassis units 103 is shown in FIG. 4. As shown in FIG. 4, chassis units 103 forming the ceiling structures of data levels 102b-d include hot aisle chassis units 103H and cold aisle chassis units 103C. The hot aisle chassis units 103H each form a portion of the ceiling structure above a hot aisle 152, and the hot aisle chassis units of the ceiling structure of data levels 102b and 102c each form part of the floor on which a hot aisle 152 of the data level above is located. The cold aisle chassis units 103C each form a portion of the ceiling structure above a cold aisle 151, and the cold aisle chassis units of the ceiling structure of data levels 102b and 102c each form part of the floor on which a cold aisle 151 of the data level above is located. As shown in FIG. 4, the data center building 101 also comprises riser chassis units which accommodate service risers extending from the services level 102a to each of the data levels 102b-d and onto the roof. The ceiling structure of levels 102a-c each comprise riser chassis 103R which include openings 160 for service conduits 161a, 161b and which define a portion of the floor of the level above. The service conduits 161a, 161b each include multiple vertical portions, spanning the height of the data levels and passing through the openings 160. The data center building 101 further comprises riser head chassis units 103RH which form a portion of the ceiling structure of data level 102d, a portion of the roof of the data center building 101, and provide a riser head structure 165 projecting above the roof-line formed by the other chassis units 103 forming the roof of the data center building 101. Service conduits 161a carry services between the services level 102a and the roof, and have portions extending out of the riser head structure 165 onto the roof, outside the building. Service conduits 161b carry services between the services level 102a and the data levels 102b-d, and extend out of the riser areas into the data areas on data levels 102b-d.

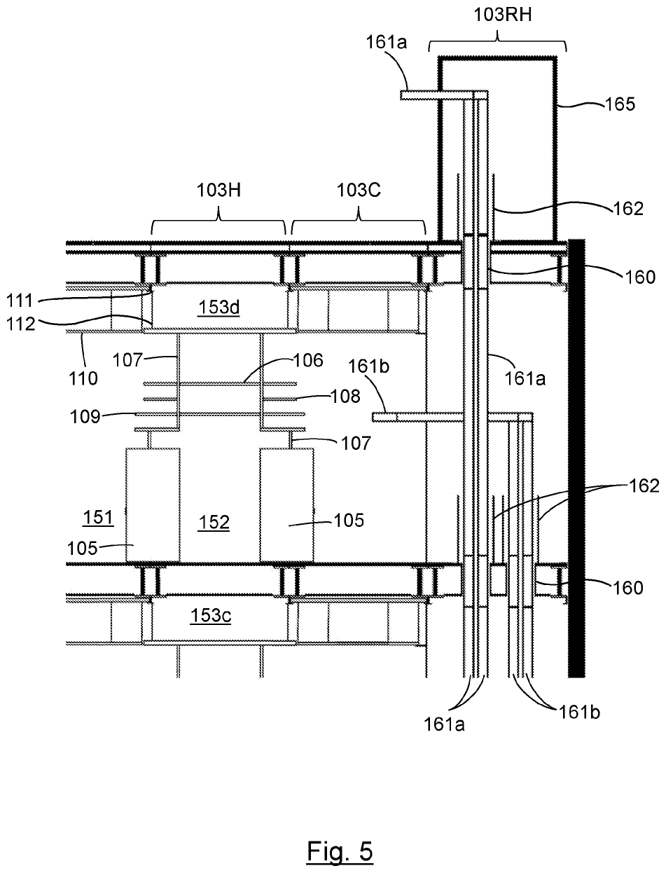

FIG. 5 shows an enlarged view of a portion of FIG. 4. As shown in FIG. 5, service cassettes 106 are suspended from brackets 111 mounted on chassis units 103, the brackets 111 also being used to secure neighboring chassis units 103 together (by fastening together brackets 111 on the neighboring chassis units 103). Also shown in FIG. 5 are safety rails 162 around the openings 160 in riser chassis units 103R and the riser head chassis unit 103RH.

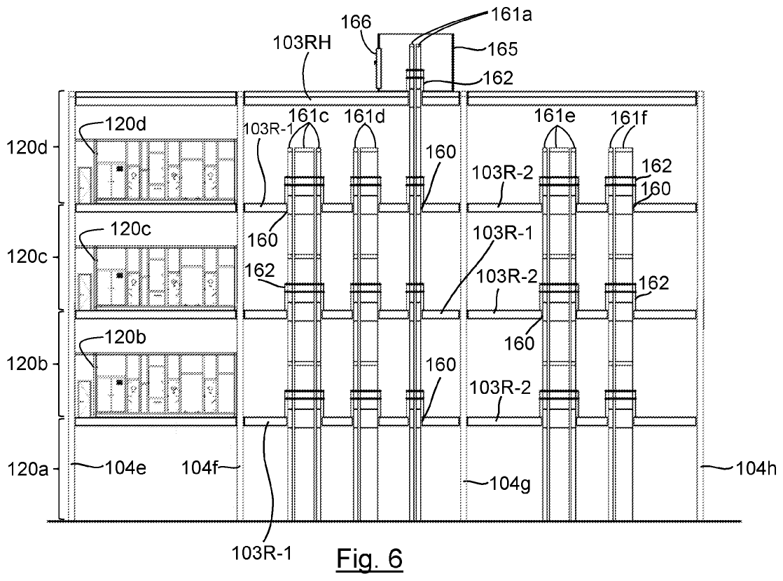

FIG. 6 shows another side cross-sectional view through the data center 101 of FIG. 1. Shown in FIG. 6 are riser chassis units 103R-1, 103R-2 forming portions of the ceiling structure of levels 102a-d. The riser chassis units 103R-1, 103R-2, 103RH each comprise openings 160 through which service conduits 161a-f pass (conduit 161b is not shown in FIG. 6). The service conduits may be in the form of racks, frames, and/or ducting, for example. Services carried by the service conduits include electrical power, data and fluids, such as fire suppressant fluids and/or refrigerant fluids. For example, service components such as cables, bus-bars and/or pipes may be supported by the service conduits. Service conduits 161c-f carry services between the services level 102a and the data levels 102b-d, and extend out of the riser areas into the data areas on data levels 102b-d. The riser head structure 165 is provided with an access door 166 providing personnel access between the riser head (i.e. the interior of the building) and the rooftop (i.e. the exterior of the building). The chassis units 103 are attached at their ends to support posts 104e-h, in the same manner by which the chassis units 103 of FIG. 1 are supported by support posts 104a-d. The riser head chassis unit 103RH is provided as a factory-finished weather-tight structure, meaning that the riser head structure is formed integrally with the chassis unit, and the chassis unit providing a single weather-tight roof section that need only be sealed with adjacent chassis units to provide a weather-tight roof. For example, flashing and/or seals between the riser head structure, the door, and the section of roof formed by the parts of the riser chassis unit not covered by the riser head section are completed prior to installation of the riser head chassis unit on the support posts on site.

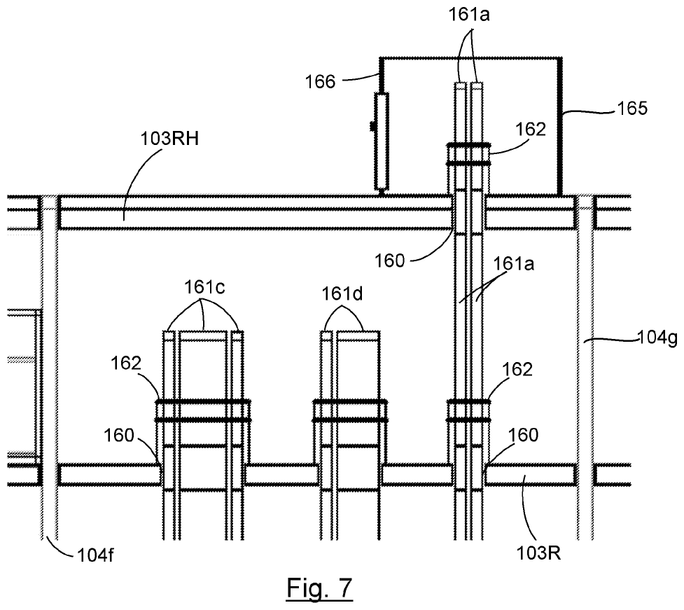

FIG. 7 shows an enlarged view of a portion of the drawing of FIG. 6, labelled with the same reference numerals as used for FIG. 6.

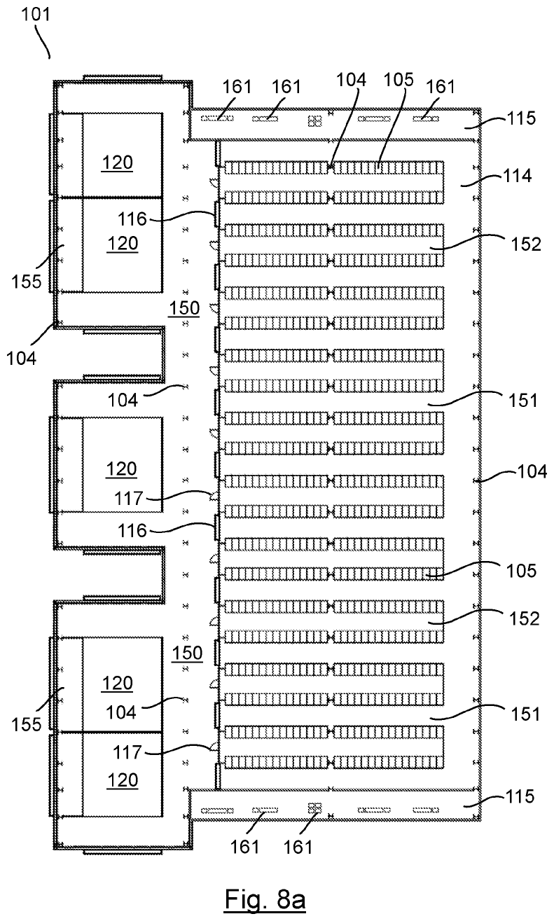

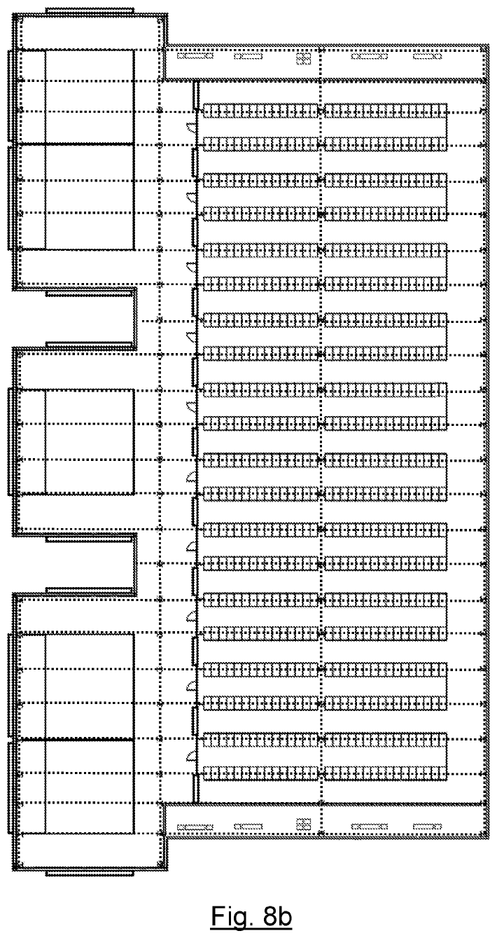

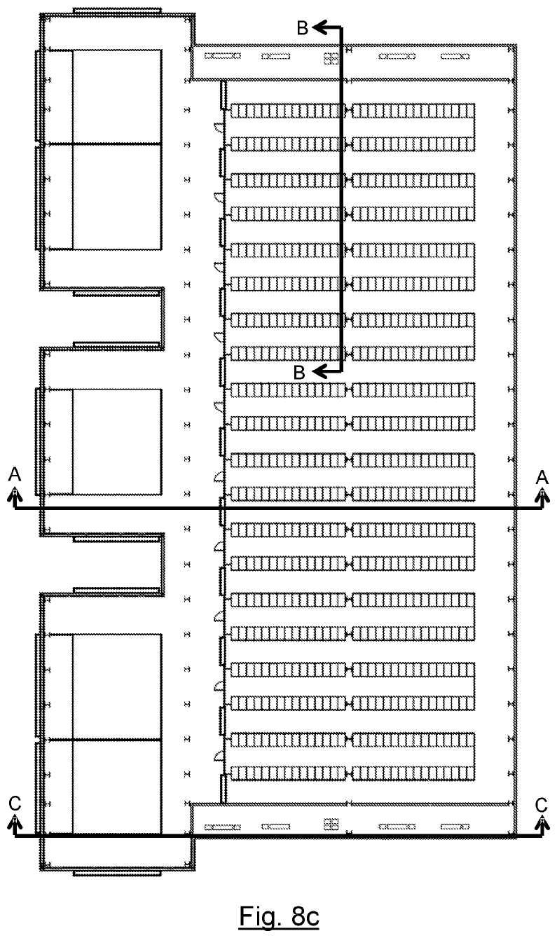

FIG. 8a shows a plan view of data level 102c of the data center 101 of FIG. 1, labelled with the same reference numerals as used in FIGS. 1-7 (except that, for clarity, the ‘c’ suffix is omitted). In the floorplan shown in FIG. 8a, the IT area of the data level includes cold aisles 151, hot aisles 152, rack storage areas accommodating racks 105, and connecting corridor 114 (which links cold aisles 151 together). As shown in FIG. 8a, riser areas 115 accommodating service conduits 161 that extend between levels are located alongside the IT area, with the riser chassis units arranged site by side with IT chassis. In use, cooling air is provided by air handler units 120, which deliver cooling air into one side cold corridor 150, which transports and distributes cold air to cold aisles 151 through vented access doors 116, which provide controlled fluid communication and personnel access between the cold corridor 150 and cold aisles 151. Examples of vented doors are disclosed in WO2010139921 (Bripco BVBA), the contents of which are incorporated herein by reference. Personnel doors 117 provide access to hot aisles 152, while also maintaining air segregation between the cold corridor 150 and the hot aisles 152.

FIG. 8b shows the plan view of FIG. 8a, overlaid with dashed lines to show the edges of chassis units forming the ceiling structure of data level 120b (that is, the chassis units that form the floor of data level 102c).

FIG. 8c shows the plan view of FIG. 8a, annotated to indicate the positions of the views of FIGS. 1, 4 and 6. Line A-A indicates the position of the view of FIG. 1. Line B-B indicates the position of the view of FIG. 4. Line C-C indicates the position of the view of FIG. 6.

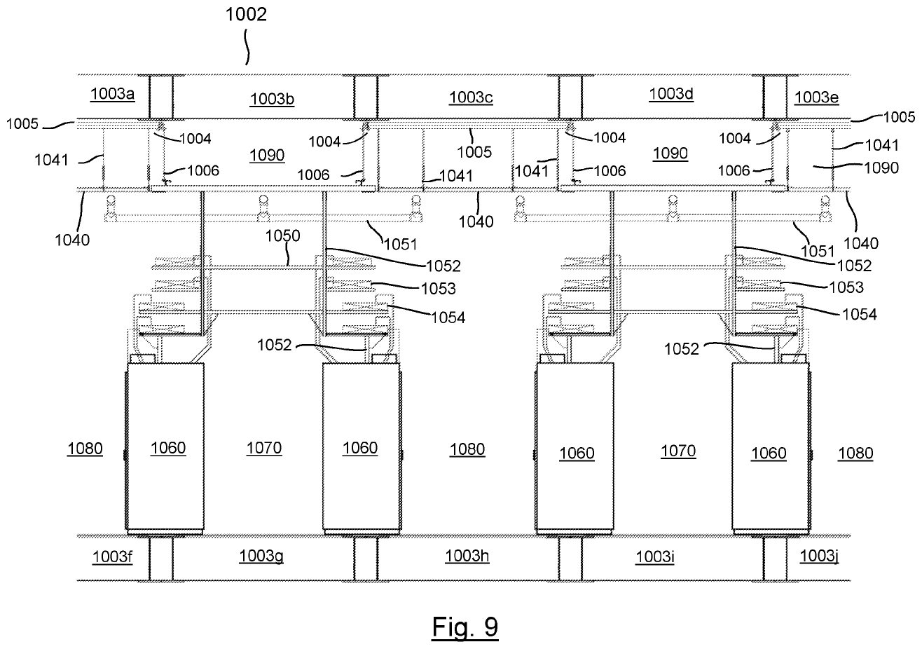

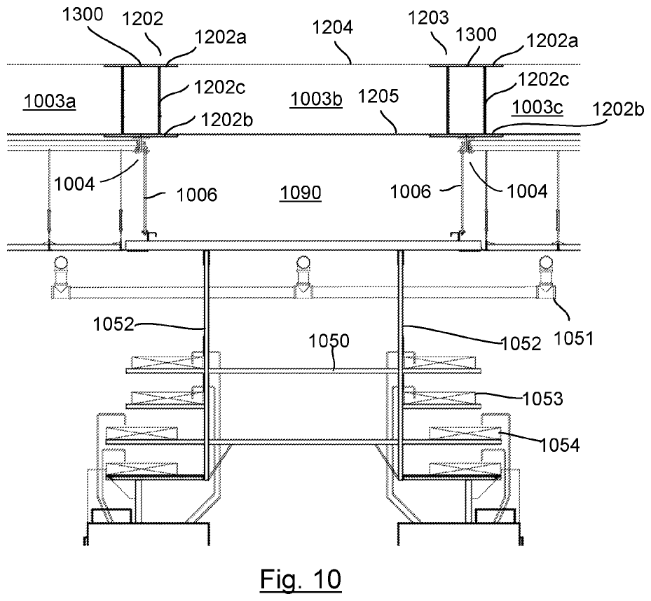

FIG. 9 shows an end cross-sectional view of another data center 1002 according to the invention. In the figure, ten chassis units 1003a-j are shown, with chassis units 1003a-e forming the ceiling and chassis units 1003f-j forming the floor of an intermediate level of the data center 1002. Levels above and below the illustrated intermediate level are omitted for clarity. Chassis units 1003a-j are arranged side-by-side. The chassis units 1003a-j are fastened together by bolts that secure together brackets 1004 arranged on adjacent chassis units. As shown in FIG. 9, joins between adjacent side-by-side chassis units 1003a-j are positioned under server racks 1060, so that the racks 1060 span the join and are supported by the side beams of two chassis units. Drop members 1006 and slot channel frame system beams 1040 are also bolted to the brackets 1004. Hot aisle service cassettes 1050 are suspended from brackets 1004 by drop members 1006, the service cassettes 1050 supporting fire suppression equipment 1051, air entrainment panels 1052 dividing hot aisles 1070 from cold aisles 1080, electrical cable trays 1053, and network cable trays 1054. Further air entrainment panels 1040 are suspended from the beams 1005 by drop rods 1041. As shown in FIG. 9, chassis units 1003b, 1003d having brackets 1004 supporting service cassettes 1050 are positioned above the hot aisles 1070, while chassis units 1003a, 1003c, 1003e having brackets 1004 supporting the further air entrainment panels 1040 are positioned above the cold aisles 1080. The hot aisles 1070 and cold aisles 1080 are shown in an alternating arrangement. Note that FIG. 9 shows only a portion of cold aisles 1080 and the associated chassis system components. Note also that the cassettes 1050 are made up of an open framework extending down from their associated chassis units 1003 and across the width of the hot aisles 1070. The air entrainment panels 1052 are mounted on the framework of the cassettes 1050, and extend along the lengths of the rows of server racks 1060 along each aisle, spanning and closing the gap between the tops of the racks 1060 and the warm air return plenum 1090. The hot aisles 1070 are in fluid communication with the overhead warm air return plenum 1090 along their length. The plenum 1090 also extends above the cold aisles 1080. Together, the hot aisles 1070 and the warm air return plenum 1090 form a hot zone, which is separated from the cold zone (comprising the cold aisles 1080 and cold corridor, not shown in FIG. 10) by the air entrainment panels 1040, 1052. The framework of each cassette 1050 is moveable along drop members 1006 to vary the height of the cassette 1050 relative to the chassis unit 1003. In practice, such movement increases/decreases the height of the plenum 1090 as the cassette is moved down/up. Each cassette 1050 may be positioned closer to the chassis unit 1003 to provide a transport configuration, e.g., if chassis units 1003 are transported with service cassettes 1050 attached, and moved to another position further from the chassis unit 1003 to provide a deployed configuration, e.g., so that the plenum 1090 has its desired height when the cassettes 1050 are in the deployed position.

FIG. 10 shows an enlarged view of a portion of the drawing of FIG. 9, with features labelled with the same reference numerals. As shown in FIG. 10, the chassis units are each made up of a pair of ‘I’ beams 1202, 1203 that extend on each side along the length of the chassis unit, each ‘I’ beam having top 1202a, 1202a and bottom flanges 1203b, 1203b, and a web 1202c, 1203c extending from the top flange 1202a, 1203a to the bottom flange 1202b, 1203b. The ‘I’ beams 1202, 1203 are joined together by cross-beams (not shown in FIG. 10) supporting an upper layer 1204 forming the top of the chassis unit 1201 and a lower layer 1205 forming the bottom of the chassis unit. Brackets 1004 are secured to and depending from the ‘I’ beams 1202, 1203 on each side of the chassis units 1003a-j. As shown in FIG. 10, the bolted together brackets 1004 hold the chassis units 1003a-j together, holding the ‘I’ beams tightly together at joins 1300. It will be appreciated that each chassis unit includes multiple pairs of C-brackets along its length, providing multiple bolted fastenings holding the chassis units together along the length of the joins 1300.

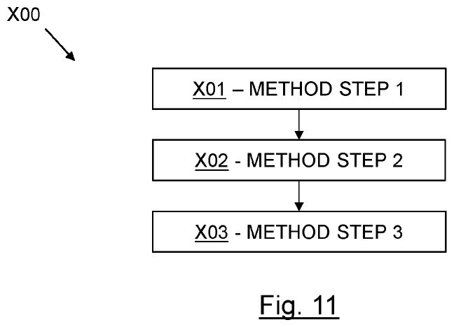

FIG. 11 depicts steps of a method X00 according to an embodiment of the invention. The method is a method of constructing a multi-level data center building. The method comprises a step X01 of bringing together at a construction site multiple prefabricated chassis units. The chassis units each have an elongate shape with a length and a width, opposed ends parallel to the width, opposed sides parallel to the length, and side beams extending along the opposed sides. The method further comprises a step X02 of, at the construction site, supporting the chassis units so that they form a ceiling structure of a first level of the building and so that the side beams of neighboring chassis units abut and are joined together. The method also comprises a step X01 of forming, above the chassis units, a plurality of cold aisles in the data center interleaved with a plurality of hot aisles in the data center such that a rack storage area is defined between each pair of adjacent hot aisle and cold aisle, and such that each such rack storage area spanning a join between neighboring chassis units. The ceiling structure so formed forms a floor of a second level of the building above the first level.

Whilst the present invention has been described and illustrated with reference to particular embodiments, it will be appreciated by those of ordinary skill in the art that the invention lends itself to many different variations not specifically illustrated herein

Where in the foregoing description, integers or elements are mentioned which have known, obvious or foreseeable equivalents, then such equivalents are herein incorporated as if individually set forth. Reference should be made to the claims for determining the true scope of the present invention, which should be construed so as to encompass any such equivalents. It will also be appreciated by the reader that integers or features of the invention that are described as preferable, advantageous, convenient or the like are optional and do not limit the scope of the independent claims. Moreover, it is to be understood that such optional integers or features, whilst of possible benefit in some embodiments of the invention, may not be desirable, and may therefore be absent, in other embodiments.

1. A multi-level data center building, wherein the data center building comprises a plurality of data levels;
wherein each data level accommodates at least ten rack storage areas positioned on a floor, each rack storage area having a width and a length and being arranged to accommodate a row of at least ten server racks, the rack storage areas separating alternating hot aisles and cold aisles, each cold aisle and each hot aisle having a width and a length;
wherein each data level comprises a ceiling structure formed from a plurality of chassis units, each chassis unit having an elongate shape with a length and a width, opposed ends parallel to the width, opposed sides parallel to the length, and side beams extending along the opposed sides;
wherein each chassis unit is supported above the floor by a plurality of support posts;
wherein the side beams of neighboring chassis units abut at side joins thereby providing a side-by-side arrangement of chassis units;
wherein the plurality of data levels includes a first data level, and a second data level positioned above the first data level;
wherein the ceiling structure of the first data level forms the floor of the second data level;
and wherein each side join between chassis units of the ceiling structure of the first data level is positioned under and extends along at least a portion of the length of a rack storage area of the second data level so that said each storage area of the second data level spans a join between neighboring chassis units.

2. The multi-level data center building according to claim 1, wherein the plurality of data levels comprises a third data level positioned above the second data level, wherein the ceiling structure of the second data level forms the floor of the third data level, and wherein each side join between cold aisle chassis units and hot aisle chassis units of the ceiling structure of the second data level is positioned under and extends along at least a portion of the length of a rack storage area of the third data level so that each rack storage area of the third data level spans a join between neighboring hot and cold aisle chassis units.

3. The multi-level data center building according to claim 2, wherein each support post supports a portion of at least one chassis unit of the ceiling structure of the first data level and a portion of at least one chassis unit of the ceiling structure of the second data level, for example wherein each support post supports a portion of two or more chassis units of the ceiling structure of the first data level and two or more chassis units of the ceiling structure of the second data level.

4. The multi-level data center building according to claim 2, wherein each chassis unit of the ceiling structure of the first data level is supported by four or more support posts that also support a chassis unit of the ceiling structure of the second data level.

5. The multi-level data center building according to claim 1, wherein the plurality of chassis units comprises a plurality of IT chassis units, wherein each IT chassis unit is arranged end to end with an adjacent IT chassis unit, optionally wherein the plurality of IT chassis units comprises a plurality of cold aisle chassis units interleaved with a plurality of hot aisle chassis units, optionally.

6. The multi-level data center building according to claim 5, wherein each end of each IT chassis unit is secured to at least one, preferably two or more, support posts, wherein said adjacent IT chassis units both are secured to and positioned on opposite sides of at least one, preferably two or more, support posts.

7. The multi-level data center building according to claim 1, wherein the combined width of two neighboring chassis units corresponds to: the width of a cold aisle, plus the width of a hot aisle, plus the width of two rack storage areas.

8. The multi-level data center building according to claim 1, wherein each data level comprises a plurality of air handling units for providing cooling air to cold aisles;
wherein the plurality of chassis units of the ceiling structure of the first data level comprises a plurality of IT chassis units and a plurality of air handler chassis units, each air handler chassis unit supporting a portion of an air handler of the second data level;
wherein the plurality of chassis units of the ceiling structure of the second data level comprises a plurality of IT chassis units and a plurality of air handler chassis units, each air handler chassis unit supporting a portion of an air handler of the third data level, when the third data level is present;
wherein each air handler chassis unit:
is joined to at least one other air handler chassis unit by a side join in a side by side arrangement;
is arranged end to end with an adjacent IT chassis unit; and,
has a width equal to the width of said adjacent IT chassis unit.

9. The multi-level data center building according to claim 1, wherein the or each data level comprises a cold air supply corridor having a length extending perpendicular to and being in fluid communication with the cold aisles of the data level to receive from the cold air supply corridor cooling air supplied to the cold air supply corridor by a plurality of air handling units, wherein the air handling units are positioned alongside and distributed along the length of the cold air supply corridor;
wherein the cold air supply corridor of the second data level, and the cold air supply corridor of the third data level if present, extends across a plurality of side joins between adjacent chassis units, such as adjacent IT chassis units.

10. The multi-level data center building according to claim 23, wherein the cold air supply corridor of the second data level, and the cold air supply corridor of the third data level if present, extends across a plurality of side joins between adjacent air handler chassis units, and spans the ends of a plurality of IT chassis units and air handler chassis units.

11. The multi-level data center building according to claim 1, comprising a service riser area accommodating data center services extending between data levels;
wherein the plurality of chassis units of the ceiling structure of the first data level comprises a plurality of riser chassis units, each riser chassis unit comprising one or more openings for accommodating passage of components of data center services though the chassis unit from a level below the chassis unit to a level above the chassis unit.

12. The multi-level data center building according to claim 1, wherein the plurality of data levels comprises an uppermost data level, the ceiling structure of the uppermost data level forming at least a portion of a roof of the multi-level data center;
optionally wherein the ceiling structure of the uppermost data level comprising at least one riser head chassis unit, wherein the riser head chassis unit comprises a roof section and a riser head structure projecting through and above the roof section, wherein the riser head chassis unit is provided with a factory-finished weather-tight seal between the roof section and the riser head structure, and wherein the riser head structure comprises a door for personnel access into the riser head structure from outside the building and one or more service inlets for accommodating passage of service components into the building from outside the building.

13. The multi-level data center building according to claim 1, wherein the chassis units have a width of from 2 m to 4 m, optionally wherein the plurality of chassis units comprises a plurality of chassis units of equal width, the plurality of chassis units of equal width comprising IT chassis units and optionally air handler chassis units.

14. The multi-level data center building according to claim 1, wherein the ceiling structure comprises one or more service cassettes suspended from IT chassis units, each service cassette comprising:
components of a plurality of data center services;
aisle air entrainment panels configured to cooperate with racks of IT equipment to segregate hot and cold aisles; and
ceiling air entrainment panels configured to segregate cold aisles from a hot air plenum disposed between the ceiling air entrainment panels and IT chassis unit, said hot air plenum being in fluid communication with one or more hot aisles.

15. The multi-level data center building according to claim 14, wherein the data center building comprises a plurality of racks of IT equipment accommodated in the rack storage areas of each data level, the racks together with air entrainment panels segregating the hot and cold aisles.

16-19. (canceled)

20. A method of constructing a multi-level data center building according to claim 1, the method comprising:
bringing together at a construction site multiple prefabricated chassis units, the chassis units each having an elongate shape with a length and a width, opposed ends parallel to the width, opposed sides parallel to the length, and side beams extending along the opposed sides;
at the construction site supporting the chassis units so that they form a ceiling structure of a first level of the building and so that the side beams of neighboring chassis units abut and are joined together; and
forming, above the chassis units, a plurality of cold aisles in the data center interleaved with a plurality of hot aisles in the data center such that a rack storage area is defined between each pair of adjacent hot aisle and cold aisle, each such rack storage area spanning a join between neighboring chassis units, the ceiling structure so formed forming a floor of a second level of the building above the first level.

21. A method according to claim 20 comprising:
providing a kit of parts;
transporting the kit of parts in a transport configuration having a first sum volume; and,
assembling the kit of parts to form at least a section of the data center having a second sum volume;
wherein the first sum volume is smaller than the second sum volume;
wherein the kit of parts is for forming at least a section of the multi-level data center building; and
wherein the kit of parts comprises a plurality of said chassis units and a plurality of said support posts, each support post configured for supporting at least a portion of each of two or more chassis units of a first data level and at least a portion of each of two or more chassis units of a second data level.

22. A method according to claim 20, wherein:
the kit of parts comprises a plurality of service cassettes configured for suspension from a chassis unit, each service cassette comprising:
components of a plurality of data center services;
aisle air entrainment panels configured to cooperate with racks of IT equipment to segregate hot and cold aisles; and
ceiling air entrainment panels configured to segregate cold aisles from a hot air plenum disposed between the ceiling air entrainment panels and said chassis unit, said hot air plenum being in fluid communication with one or more hot aisles;
wherein the service cassettes are movable between:
a first transport configuration in which the ceiling air entrainment panels are spaced apart from said chassis unit by a first distance; and
a second deployed position in which the ceiling air entrainment panels are spaced apart from said chassis unit by a second distance;
wherein the first distance is less than the second distance;
and wherein the service cassettes are fastened to the chassis units and arranged in the transport configuration during the transporting step, and the method comprises moving the service cassettes from the transport configuration to the deployed configuration during or after the assembling step.

23. The multi-level data center building according to claim 8,
wherein the or each data level comprises a cold air supply corridor having a length extending perpendicular to and being in fluid communication with the cold aisles of the data level to receive from the cold air supply corridor cooling air supplied to the cold air supply corridor by a plurality of air handling units, wherein the air handling units are positioned alongside and distributed along the length of the cold air supply corridor;
wherein the cold air supply corridor of the second data level, and the cold air supply corridor of the third data level if present, extends across a plurality of side joins between adjacent chassis units, such as adjacent IT chassis units.

24. The multi-level data center building according to claim 12,
wherein the ceiling structure of the uppermost data level comprising at least one riser head chassis unit, wherein the riser head chassis unit comprises a roof section and a riser head structure projecting through and above the roof section, wherein the riser head chassis unit is provided with a factory-finished weather-tight seal between the roof section and the riser head structure, and wherein the riser head structure comprises a door for personnel access into the riser head structure from outside the building and one or more service inlets for accommodating passage of service components into the building from outside the building.
